(19) United States
(12) Patent Application Publication
(10) Pub. No.: US 2026/0088791 A1
(43) Pub. Date: Mar. 26, 2026

(54) ELECTRONIC CIRCUIT, ELECTRONIC SYSTEM, AND METHOD

(71) Applicant: Infineon Technologies Austria AG, Villach (AT)

(72) Inventors: Jong Uk LEE, Goyang-si (KR); Tae Sung KWON, Seoul (KR); Jun Bae LEE, Seoul (KR); Bok Keun SONG, Seoul (KR); Karl Egil NORLING, Villach (AT)

(21) Appl. No.: 19/332,936

(22) Filed: Sep. 18, 2025

(30) Foreign Application Priority Data
Sep. 25, 2024 (DE) 102024209245.2

(51) Int. Cl. H03H 1/00; H03K 17/0812

(52) U.S. Cl. CPC H03H 1/0007; H03K 17/08122

(57) ABSTRACT

The disclosure relates to an electronic circuit, an electronic system, and a method. The electronic circuit includes a fault output node switchable between a fault state indicating a fault operating state and a normal state indicating a normal operating state, the electronic circuit further including: a fault detector configured to assert a number of fault event signals of a plurality of fault event signals, wherein each of the plurality of fault event signals indicates a different fault event associated with the electronic circuit, a fault mode signal generator configured to generate a fault mode signal based on the asserted number of fault event signals, and a fault output node control unit configured to receive the fault mode signal and, in response to receiving the fault mode signal, switch the fault output node to the fault state.

### RELATED APPLICATION

This application claims priority to German Patent Application No. 102024209245.2, filed on Sep. 25, 2024, entitled “ELECTRONIC CIRCUIT, ELECTRONIC SYSTEM, AND METHOD”, which is incorporated by reference herein in its entirety.

### TECHNICAL FIELD

The present disclosure relates to an electronic circuit including a fault output node switchable between a fault state indicating a fault operating state and a normal state indicating a normal operating state, an electronic system including the electronic circuit and a control unit, and a method for operating an electronic circuit.

### BACKGROUND

Gate drivers are used in a wide variety of applications for switching power transistors on and off according to a drive signal generated by a control logic. Example applications are motor drives, power converters, power supplies and many others. In a basic form, the gate driver may be seen as a signal amplifier that amplifies the control signal from a logic voltage level, such as 3.3 V or 5 V, for example, to a voltage level that is suitable to drive a controlled power transistor, such as 15 V, for example, and also provides for a sufficiently high current sourcing/sinking capability required to charge a gate capacitance of the controlled switch. More sophisticated gate drivers may integrate additional functions, such as soft-switching control, dead time insertion, sensing and/or protection functions. In particular, gate drivers may integrate a fault detection function that is configured to detect faults occurring in the gate driver, the controlled power transistor and/or the driven load. Example faults include an overvoltage or an undervoltage of the gate driver power supply, an overvoltage or overcurrent or overtemperature event at the controlled power transistor and/or a short circuit event.

It is desired to report detected faults from the gate driver to the control logic. For this, many gate drivers include a fault output terminal. For example, the fault output terminal may be maintained at a specific voltage level during normal operation of the gate driver and the controlled power transistor, and may be pulled low when a fault is detected. Thus, the control logic may be informed that a fault event was detected by the gate driver. However, based on this kind of fault indication, the control logic has no information regarding the type of fault event that occurred. It may be beneficial to also signal the kind of fault to the control logic, which may allow a more appropriate reaction to the fault event.

### SUMMARY

According to a first aspect, the present disclosure provides an electronic circuit including a fault output node switchable between a fault state indicating a fault operating state and a normal state indicating a normal operating state, the electronic circuit including: a fault detector configured to assert a number of fault event signals of a plurality of fault event signals, wherein each one of the plurality of fault event signals indicates a different fault event associated with the electronic circuit, a fault mode signal generator configured to generate a fault mode signal based on the asserted number of fault event signals, and a fault output node control unit configured to receive the fault mode signal and, in response to receiving the fault mode signal: switch the fault output node to the fault state, and output the fault mode signal at the fault output node by switching the fault output node in accordance with the fault mode signal.

According to a second aspect, the present disclosure provides an electronic system, including: a control unit configured to control the electronic system, and the electronic circuit of the first aspect, wherein: the control unit is connected to the fault output node of the electronic circuit and configured to: detect a fault operating state of the electronic system based on the fault output node being switched to the fault state, receive the fault mode signal at the fault output node, and decode the received fault mode signal.

According to a third aspect, the present disclosure provides a method for operating an electronic circuit, the method including the steps of: Asserting a number of fault event signals of a plurality of fault event signals, wherein each one of the plurality of fault event signals indicates a different fault event associated with the electronic circuit, Generating a fault mode signal based on the asserted number of fault event signals, Switching a fault output node of the electronic circuit to a fault state, and Providing the fault mode signal at the fault output node.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a schematic block diagram of a first embodiment of an electronic circuit in accordance with the present disclosure.

FIG. 2 illustrates a schematic block diagram of a second embodiment of an electronic circuit in accordance with the present disclosure.

FIG. 3 illustrates a schematic block diagram of an embodiment of a fault output node control unit in accordance with the present disclosure.

FIG. 4 illustrates a schematic block diagram of a third embodiment of an electronic circuit in accordance with the present disclosure.

FIGS. 5A and 5B each illustrate a schematic block diagram of a respective embodiment of an electronic circuit in accordance with the present disclosure.

FIG. 6 illustrates a schematic block diagram of an analog implementation of an electronic circuit in accordance with the present disclosure.

FIG. 7 illustrates a schematic signal diagram of an embodiment of an electronic circuit in accordance with the present disclosure.

FIG. 8 illustrates a schematic block diagram of an embodiment of an electronic system in accordance with the present disclosure.

FIG. 9 illustrates a schematic block diagram of a method to operate an electronic circuit in accordance with the present disclosure.

### DETAILED DESCRIPTION

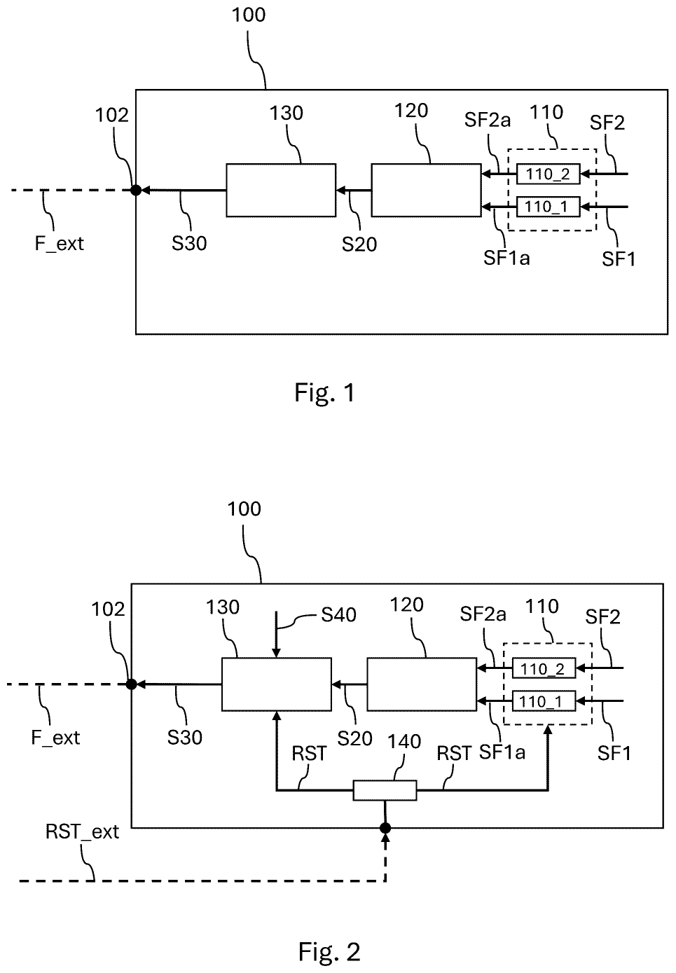

The examples described herein provide an electronic circuit with fault reporting functionality. FIG. 1 illustrates a schematic block diagram of a first embodiment of an electronic circuit 100. The electronic circuit 100 includes a fault output node 102 that is switchable between a fault state and a normal state. The fault state indicates a fault operating state and the normal state indicates a normal operating state. The operating state indication provided at the fault output node 102 may relate to the electronic circuit 100 or to a further electronic circuit or component that is connected to the electronic circuit 100, such as, for example, a power transistor, a power converter, a circuit breaker, and the like. The electronic circuit 100 may be fully or partially be implemented as an integrated circuit, and/or may be fully or partially implemented using discrete electronic components. In one or more embodiments, the electronic circuit 100 may by implemented as an analog logic circuit, and/or may include one or more digital logic circuits, such as, for example, a digital signal processor (DSP), a digital finite state machine (FSM), a programmable logic controller (PLC) or a processing unit that may be configured to execute executable instructions.

The electronic circuit 100 includes a fault detector 110 configured to assert a number of fault event signals SF1a, SF2a of a plurality of fault event signals SF1, SF2. Each one of the plurality of fault event signals SF1, SF2 indicates a different fault event associated with the electronic circuit 100. It is noted that there may be more than two fault event signals that are received and asserted by the fault detector.

For example, each one of the plurality of fault event signals SF1, SF2 may be provided by a corresponding fault event detector that is connected to the fault detector 110. The plurality of fault event detectors may be external to the electronic circuit 100, or some or all of the fault event detectors may be part of the electronic circuit 100. Example fault event detectors are over-/undervoltage detectors, overcurrent detectors, short circuit detectors, overtemperature detectors, and others. For example, the fault detector 110 may include a plurality of inputs that are respectively connected the fault event detectors and configured to receive the respective fault event signal SF1, SF2. In one or more embodiments, a fault event detector may provide an analog or digital measurement signal of an associated physical quantity, and a fault detection logic may determine the fault event based on a magnitude of the measurement signal. In one or more implementations, the detection logic may be integrated in the fault detector 110.

For example, the plurality of fault event signals includes at least two of the following: an overcurrent fault event signal, an overvoltage fault event signal, an undervoltage fault event signal, a short-circuit fault event signal, an overtemperature fault event signal and a not ready fault event signal.

The overcurrent fault event signal may indicate an overcurrent condition that is present or has occurred in the electronic circuit 100 and/or in a further electronic circuit or component connected to the electronic circuit 100. For example, the overcurrent condition may occur in a power transistor connected to the electronic circuit 100.

The overvoltage fault event signal may indicate an overvoltage condition that is present or has occurred in the electronic circuit 100 and/or in a further electronic circuit or component connected to the electronic circuit 100. For example, the overvoltage condition may occur in a power supply configured to supply the electronic circuit 100 with electrical energy, and/or in a DC bus supply voltage connected to a load node of a power transistor connected to the electronic circuit 100 and configured to provide a load with electrical power.

The undervoltage fault event signal may indicate an undervoltage condition that is present or has occurred in the electronic circuit 100 and/or in a further electronic circuit or component connected to the electronic circuit 100. For example, the undervoltage condition may occur in a power supply configured to supply the electronic circuit 100 with electrical energy.

The short-circuit fault event signal may indicate a short-circuit condition that is present or has occurred in the electronic circuit 100 and/or in a further electronic circuit or component connected to the electronic circuit 100. For example, the short-circuit condition may occur in a power transistor connected to the electronic circuit 100, such as, for example, a source-drain short, emitter-collector short, emitter-gate short, source-gate short, or may occur in a half-bridge connected to the electronic circuit 100, such as a shoot-through event, or the like.

The overtemperature fault event signal may indicate an overtemperature condition that is present or has occurred in the electronic circuit 100 and/or in a further electronic circuit or component connected to the electronic circuit 100. For example, the overtemperature condition may occur in a power transistor connected to the electronic circuit 100.

The not ready fault event signal may indicate that the electronic circuit 100 and/or a further electronic circuit or component connected to the electronic circuit 100 is not ready for normal operation. For example, a protection function, a sensing function or the like of the electronic circuit 100 or further electronic circuit or component connected to the electronic circuit 100 may be in a not-ready state if a supply voltage or a reference voltage or the like is not provided with an adequate value.

The electronic circuit 100 further includes a fault mode signal generator 120 that is configured to generate a fault mode signal S20 based on the asserted number of fault event signals SF1a, SF2a. The fault mode signal S20 is indicative of at least one fault event as indicated by the fault event signals SF1, SF2 and asserted by the fault detector 110. For example, the fault mode signal generator 120 receives the asserted fault mode event signals SF1a, SF2a at an input connected to the fault detector 110. We note that there may be more than two asserted fault event signals SF1a, SF2a that are received at the fault mode signal generator 120 and encoded in the fault mode signal S20.

For example, the fault mode signal S20 encodes at least one asserted fault event signal SF1a, SF2a, and may encode two or more asserted fault event signals SF1a, SF2a. For example, the fault mode signal generator 120 may encode all fault event signals that are asserted by the fault detector within a predefined time interval. For example, the time interval may be triggered when a first fault event signal is asserted. Alternatively, the time interval may be triggered by a clock signal or other event.

The electronic circuit 100 further includes a fault output node control unit 130 configured to receive the fault mode signal S20. In response to receiving the fault mode signal S20, the fault output node control unit 130 switches the fault output node 102 to the fault state, and outputs the fault mode signal S20 at the fault output node 102 by switching the fault output node 102 in accordance with the fault mode signal S20.

For example, the fault output node control unit 130 controls the fault output node 102 using a fault output node control signal S30, which includes switching of the fault output node 102 to the fault state and switching fault output node 102 in accordance with the fault mode signal S20. Thus, fault output node control signal S30 is configured to encode the asserted fault event signals SF1a, SF2a, since these are encoded in fault mode signal S20 and the information of fault mode signal S20 is also present in fault output node control signal S30. For example, fault output node control unit 130 may be configured to first switch the fault output node 102 to the fault state for a predefined fault indication time interval, and then switch the fault output node 102 according to the fault mode signal S20.

An external electronic circuit, such as a controller or the like, may receive an external fault signal F_ext from the fault output node 102. The external fault signal F_ext may comprise information that is essentially identical to the information of fault output node control signal S30, and thus may also encode the asserted fault event signals SF1a, SF2a. Here, “external” may mean that the respective electronic circuit may be implemented in another chip than the electronic circuit 100, but may reside in a shared or common housing, or may be arranged in another housing, but may be arranged in a same package or device, or may be arranged in another package.

Based on the above, the electronic circuit 100 described referring to FIG. 1 may be configured to provide, at a single fault output node 102, a signal comprising information that a fault is present or has occurred and information that allows to identify exactly which kind of fault event (single fault) or fault events (plural faults) from a plurality of possibly fault events has occurred. This allows an external electronic circuit, such as a controller or the like, to implement measures to overcome or resolve the fault or the faults and ensure stable, efficient, and reliable operation of the electronic circuit 100 or further electronic circuit or component connected to the electronic circuit 100.

FIG. 2 illustrates a schematic block diagram of a second embodiment of an electronic circuit 100. The electronic circuit 100 shown in FIG. 2 may have the same or similar features as the electronic circuit of FIG. 1, which will not be described again here. In addition, the electronic circuit 100 may include a reset unit 140 that is configured to reset the fault detector 110 and control the fault output node control unit 130 to switch the fault output node 102 to the normal state. For example, the reset unit 140 may provide an internal reset signal RST to the fault detector 110 and the fault output node control unit 130. For example, the reset unit 140 may be configured to provide the internal reset signal RST when a predefined reset time interval has elapsed after the fault output node control unit 130 has switched the fault output node 102 to the fault state. In this case, the electronic circuit 100 may reset itself after the predefined reset time interval. If the fault still persists at this time, the fault output node control unit 130 may set the fault output node to the fault state again, or it may be configured to maintain the fault output node 102 in the fault state irrespective of the internal reset signal RST if the fault event persists. Alternatively or additionally, the reset unit 140 may be configured to receive an external reset signal RST_ext and, in response to receiving the reset signal RST_ext, reset the fault detector 110 and control the fault output node control unit 130 to switch the fault output node 102 to the normal state. The external reset signal RST_ext may be received at the reset unit 140 from an external electronic circuit, such as a controller. For this, a reset input node may be provided, for example.

In some embodiments, the fault output node control unit 130 may be configured to output the fault mode signal S20 at the fault output node 102 in response to the reset unit 140 receiving the reset signal RST_ext. Thus, the fault output node 102 may be maintained in the fault state until the reset signal RST_ext is received, and only then switch the fault output node 102 in accordance with the fault mode signal S20. This allows an external electronic circuit, such as a controller, to control the timing of the signaling of the fault mode signal S20.

In some embodiments, the fault output node control unit 130 may be configured to output the fault mode signal S20 at the fault output node 102 in response to receiving a fault mode signal release signal (not shown). For example, the fault mode signal release signal may be received from an external electronic circuit, such as a controller, and may be independent from the reset signal RST_ext. For example, the fault mode signal release signal may be received at the same node as the reset signal RST_ext.

In some embodiments, the fault output node control unit 130 may be configured to output the fault mode signal S20 at the fault output node 102 repeatedly, for example as long as the fault event persists and/or the electronic circuit 100 is not reset. For example, fault output node control unit 130 may output the fault mode signal S20 for a first time immediately after the fault event has occurred, and then again after a predefined time interval has elapsed. This may be repeated on a periodic basis, for example. In addition or alternatively, the fault output node control unit 130 may be configured to output a “new” fault mode signal S20 at the fault output node 102 again when a further fault event SF1, SF2 is detected by the fault detector 110 as long as the electronic circuit 100 is not reset. The “new” fault mode signal S20 encodes the first fault event(s) and the further fault events.

In some embodiments, the fault detector 110 may include a plurality of fault event assertion units 110_1, 110_2. For example, each fault event assertion unit 110_1, 110_2 includes an input, a storage element, and an output, and is configured to receive one fault event signal SF1, SF2 at the input, store the received fault event signal SF1, SF2 in the storage element, and assert the stored fault event signal SF1a, SF2a at the output. By increasing the number of fault event assertion units 110_1, 110_2, the fault detector 110 may be configured to collect and report a larger number of different fault events.

In some embodiments, the fault output node control unit 130 may be configured to receive an electrical signal S40 that is indicative of a measurement value relating to the operation of the electronic circuit 100, and to provide an analog signal corresponding to the received electrical signal at the fault output node 102 during the normal operating state. Thus, in this embodiment, the fault output node 102 is also used to output an analog measurement signal to an external electronic circuit, such as a controller, during the normal operating state. For example, the electronic circuit 100 may include one or more sensors or sensor inputs (not shown), which may be configured to generate the electrical signal S40 and provide it to the fault output node control unit 130. Example sensors are a voltage sensor, a current sensor, a temperature sensor, or the like. Thus, the electrical signal S40 may be indicative of a voltage, a current or temperature relating to the operation of the electronic circuit 100. The electrical signal S40 may be an analog or a digital signal. The analog signal output via the fault output node 102 may be a current or a voltage signal.

In some embodiments, the fault output node control unit 130 may be configured to output the fault mode signal S20 by switching the fault output node 102 to one of a plurality of distinct states corresponding to the fault mode signal S20.

The plurality of distinct states may be, for example, different voltage levels and/or different current levels and/or different signal properties, such as a PWM signal having different duty cycles, or the like. For example, each one of the plurality of distinct states may correspond to a fault event or a specific combination of fault events, such that an external electronic circuit, such as a controller, may determine which fault event or fault events are asserted by the electronic circuit 100. For example, three distinct states may be used to indicate the occurrence of a first fault event, a second fault event, or both the first and second fault event, by setting the fault output node 102 to a first state, a second state, or a third state. In one embodiment, the fault mode signal S20 is a digital signal, and the fault node output control unit 130 includes a digital-to-analog converter to convert the fault mode signal S20 into one of the plurality of distinct states.

In some embodiments, the fault mode signal S20 may be a binary signal including a plurality of data bits and the fault output node control unit 130 is configured to output the fault mode signal S20 by switching the fault output node 102 between a first state and a second state in accordance with the binary fault mode signal S20.

In this embodiment, the binary fault mode signal S20 may encode the information about the fault events SF1a, SF2a as asserted by the fault detector 110. Depending on the number of data bits of the fault mode signal S20, the number of distinctive fault events may be increased. For example, using two data bits allows to distinguish four different states (00, 01, 10, 11). For example, the first state and the second state may be a first and second voltage level, such as, e.g., 0 V and +5 V, or the like. An external electronic circuit, such as a controller or the like, may decode the fault event information provided at the fault output node 102.

In some embodiments, outputting the fault mode signal S30 may include switching the fault output node 102 between the fault state and the normal state. In this case, the same circuit elements that are used to indicate a fault or a normal operation may be re-used to provide the fault mode signal, which may be beneficial to reduce the bill of materials and device complexity.

In some embodiments, the binary fault mode signal S20 may include at least three data bits.

Three data bits allow to distinguish between eight different states (000, 001, 010, 100, 011, 101, 110, 111). This is a good size to distinguish between three different fault events. For example, with three different fault events A, B and C, and three data bits, the fault mode signal S20 may encode the following fault event information: only A, only B, only C, A and B, A and C, B and C, A and B and C, which requires seven different states. Thus, there is one additional state that can be used for encoding, for example, a fourth fault event that can only occur isolated, that is, not in combination with any other fault event. One example of such fault event may be a “not ready” state relating to the electronic circuit 100, which may be used to indicate that the electronic circuit 100 is not ready for normal operation. Here, “normal operation” may be a state in which the electronic circuit 100 is ready for detecting fault event signals and generate and output a corresponding fault mode signal S20.

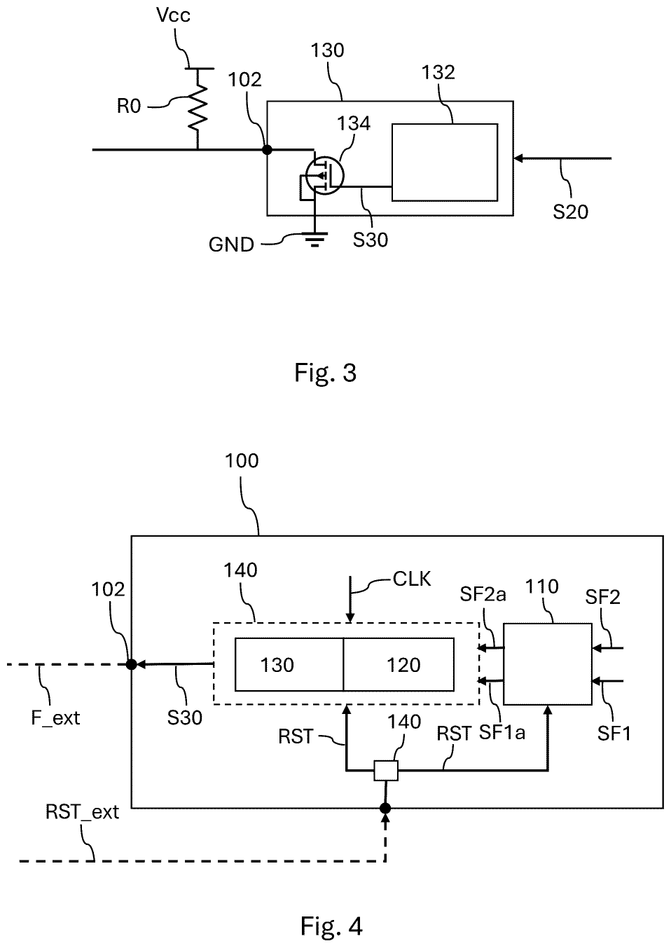

In some embodiments, the fault output node control unit 130 may be configured to control a switching device 134 connected between the fault output node 102 and a reference potential GND to switch between a blocking state and a conductive state. For example, as shown in FIG. 3, the switching device 134 may be a normally-off MOSFET (metal-oxide semiconductor field-effect transistor), which has a source terminal connected to the reference potential GND, such as a ground potential, and a drain terminal connected to the fault output node 102. This configuration may be referred to as “open drain”. The fault output node control unit 130 may comprise a logic block 132 including a gate driver for driving the MOSFET 134. In this example, the logic block 132 may be configured to receive the fault mode signal S20 and to generate and provide the fault output node control signal S30 as a gate drive signal to the MOSFET 134, to switch the MOSFET 134 between on and off states. It is noted that other switching devices, such as an IGBT (insulated gate bipolar transistor) or HEMT (high electron mobility transistor) or relays, may be used instead of the MOSFET.

In the example of FIG. 3, the fault output node 102 may be connected to a voltage Vcc via a pull-down resistor R0 externally. Therefore, as long as the MOSFET 134 is in the off state (blocking state), a voltage at the fault output node 102 may essentially correspond to the voltage Vcc, which may be used to indicate the normal operating state, for example. As soon as the MOSFET 134 turns on (conductive state), the voltage of the fault output node 102 will be pulled to the reference potential GND, which may be used to indicate the fault state. This implementation allows to provide a binary signal at the fault output node 102, for example the binary fault mode signal S20, by switching the MOSFET 134 on and off correspondingly. For example, the fault output node control signal S30 may include a high level for a first time interval to pull the fault output node 102 low during the first time interval and indicate that a fault event SF1, SF2 has occurred, and may include switching between high level and low level in accordance with the binary fault mode signal S20 to output the fault mode signal S20 at the fault output node 102.

In some embodiments, the fault output node control unit 130 may be configured to output the data bits of the binary fault mode signal S20 synchronous with a clock signal CLK (see FIG. 4).

The clock signal CLK may be an internal clock signal or may be an external clock signal. For example, the clock signal CLK may be provided by an external electronic circuit, such as a controller. In case of an internal clock signal, the internal clock signal may also be synchronized to or may be used to synchronize the fault output node control signal S30 with an external clock signal.

In the embodiment shown in FIG. 3, the output of the binary fault mode signal S20 may be synchronous with an operating cycle of an external electronic circuit, such as a controller.

In some embodiments, the fault output node control unit 130 may be configured to output the data bits of the binary fault mode signal S20 with a synchronization signal corresponding to every bit.

This allows the external electronic circuit to synchronize a read-out of the signal provided at the fault output node 102. Thus, the transmission of the fault mode signal S20 at the fault output node 102 to an external electronic circuit is improved.

For example, the synchronization signal may be a synchronization bit, such as a high level pulse preceding every data bit of the binary fault mode signal S20. The high level pulse, e.g., the rising flank of the pulse, may be used to trigger a sampling of the fault node output 102 after a predefined period has elapsed, where the high or low level of the fault output node 102 at the sampling time indicates a “1” or “0” (or vice versa). Alternatively, the rising flank of the pulse may be used to trigger an integration of the signal at the fault output node 102, and the sampling is done after the predefined period on the integrated signal. Using the integrated signal instead of a direct sample may be more robust against noise.

In further embodiments, the fault output node control unit 130 may be configured to output the data bits of the binary fault mode signal S20 using a line code. Examples are NRZ-L (non-return-to-zero level), NRZ-M (non-return-to-zero mark), NRZ-S (non-return-to-zero space), RZ (return to zero), Manchester (also referred to as Biphase-L), Biphase-M or Biphase-S.

In some embodiments, at least one of the fault detector 110, the fault mode signal generator 120 and the fault output node control unit 130 may be implemented as a digital circuit 150.

For example, as shown in FIG. 4, the fault mode signal generator 120 and the fault output node control unit 130 are implemented in a digital circuit 150. The digital circuit 150 may be implemented as a digital state machine that is clocked by clock signal CLK. The clock signal CLK may be generated internal of the electronic circuit 100 or may be provided from outside the electronic circuit 100. The digital circuit 150 may also be embodied as a digital signal processor (DSP), a digital finite state machine (FSM), a programmable logic controller (PLC) or a processing unit that may be configured to execute executable instructions.

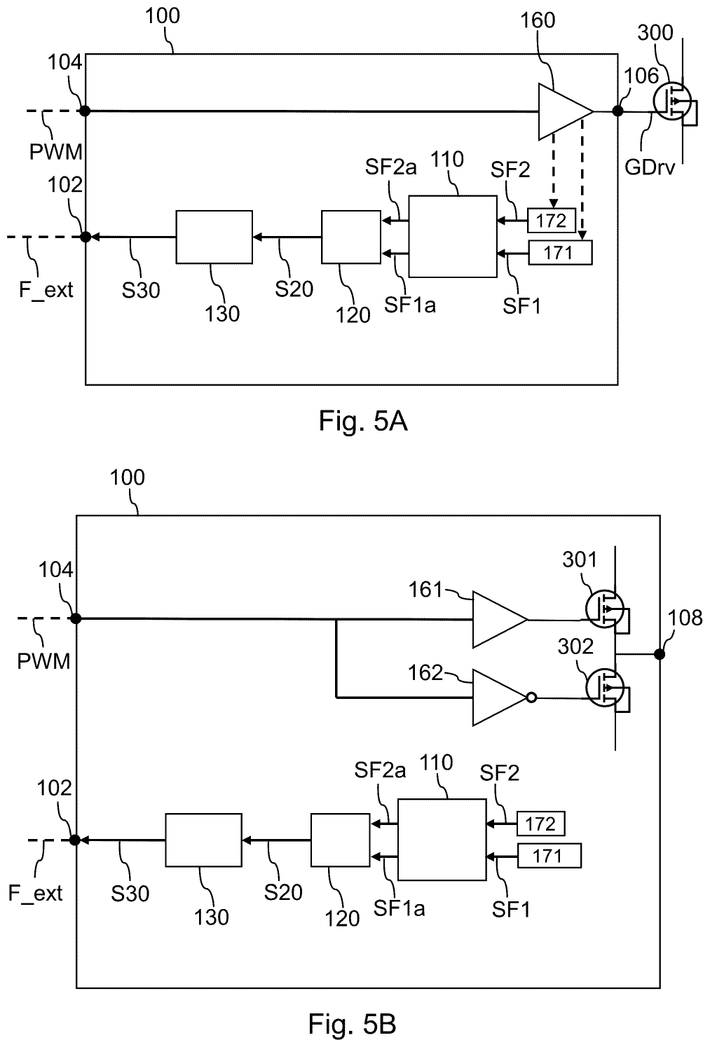

FIG. 5A illustrates a schematic block diagram of a fourth embodiment of an electronic circuit 100 in accordance with the present disclosure. The electronic circuit 100 of FIG. 5A may have the same elements as the embodiments described with reference to FIG. 1-4, which are not described again. In the example embodiment shown in FIG. 5A, the electronic circuit 100 further comprises a gate driver 160 that is configured to control a switching state of a connected power transistor 300 based on a control signal PWM, which may be a pulse-width modulation signal. The control signal PWM may be provided from an external electronic circuit at a control signal input node 104, and is provided to the gate driver 160. The gate driver 160 the provides a gate drive signal GDrv according to the control signal PWM at an output node 106, to which the gate of the power transistor 300 is connected. In addition, the electronic circuit 100 may comprise at least two fault event detectors 171, 172 that are each configured to detect a respective fault operating state of at least one of the gate driver 160 and the connected power transistor 300 and to output a corresponding fault event signal SF1, SF2. For example, the fault event detectors 171, 172 are implemented as a current sensor 171 and a voltage sensor 172 that are configured to sense an overcurrent and overvoltage at the power transistor 300. Thus, they output the respective fault event signal SF1, SF2 in case of an overcurrent or an overvoltage occurring at the power transistor 300.

FIG. 5B illustrates a schematic block diagram of a further embodiment of an electronic circuit 100 in accordance with the present disclosure. The electronic circuit 100 of FIG. 5B may have the same elements as the embodiments described with reference to FIGS. 1-4 and 5A, which are not described again. In the example embodiment shown in FIG. 5B, the electronic circuit 100 further comprises a plurality of power transistors 301, 302 connected to at least one load node 108 and configured to provide output power to the at least one load node 108, and at least two fault event detectors 171, 172 configured to detect a fault operating state of the electronic circuit 100 and to output a corresponding fault event signal SF1, SF2.

For example, as shown in FIG. 5B, the electronic circuit 100 may include two power transistors 301, 302 arranged in a half-bridge arrangement, and the load node 108 is connected between the two power transistors 301, 302. In this case, the electronic circuit 100 may include two gate drivers 161, 162 (e.g., a high-side and a low-side gate driver) to drive the two power transistors 301, 302 between switching states in accordance with the control signal PWM. In this case, at least the high-side gate driver 161 may be implemented as an isolated gate driver that includes at least one of junction isolation, level-shifter, or galvanic isolation. For example, the two gate drivers 161, 162 may operate the power transistors 301, 302 inversely based on the control signal PWM, as indicated for the low side driver 162. The electronic circuit may further include two fault event detectors 171, 172 configured to detect fault operating states of the electronic circuit 100. In some implementations, the electronic circuit 100 may implement an integrated motor inverter with a plurality of phases. However, other arrangements of the plurality of power transistors 301, 302 are also possible, such as parallel arrangements and/or independent arrangements.

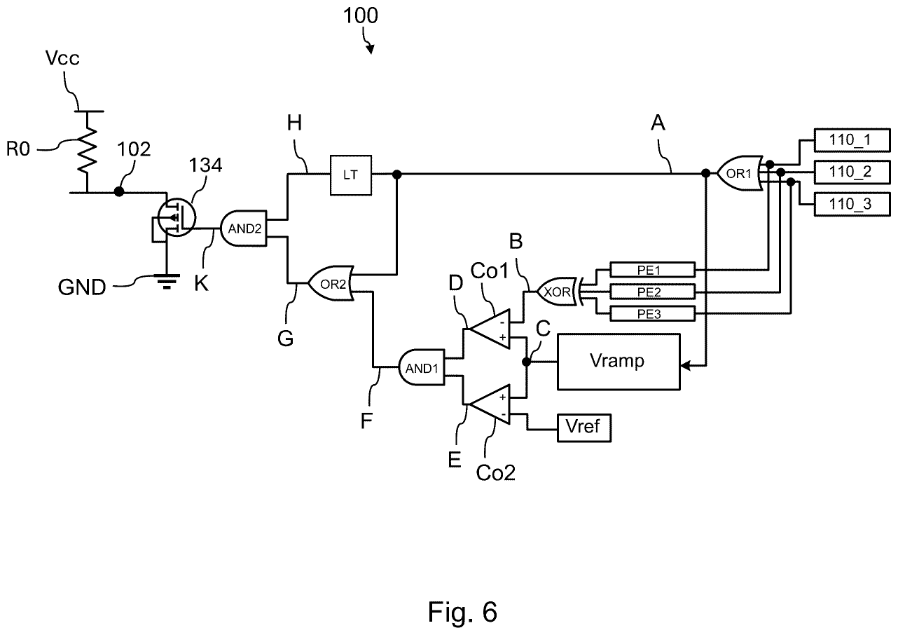

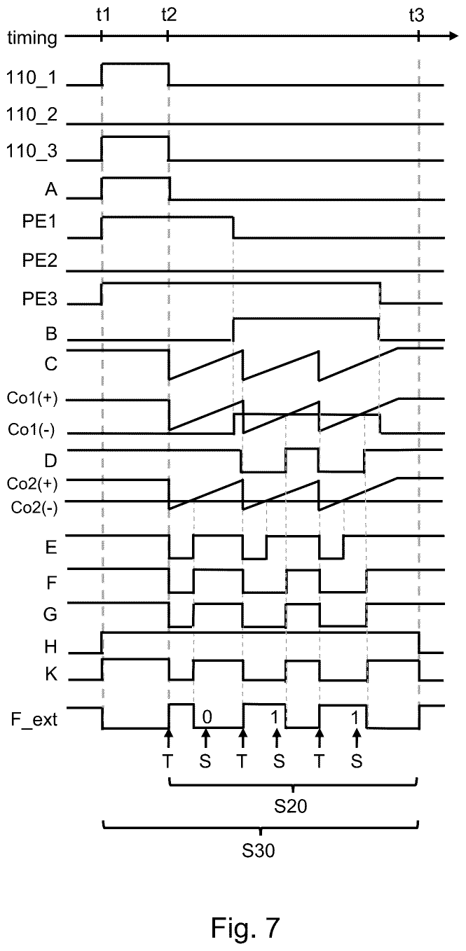

FIG. 6 illustrates a schematic block diagram of an example analog implementation of an electronic circuit 100 in accordance with the present disclosure, and FIG. 7 illustrates a corresponding schematic signal diagram of the analog implementation shown in FIG. 6.

The electronic circuit 100 of FIG. 6 has a fault detector 110 including three fault event assertion units 110_1, 110_2, 110_3 for receiving and asserting different fault event signals, and is configured to encode and output a binary fault mode signal S20 that includes information about which of the three faults have occurred. In the example of FIG. 6, the electronic circuit 100 includes a switching device 134 connected between the fault output node 102 and a reference potential GND, as described in detail referring to FIG. 3. In the following, operation of the analog electronic circuit 100 of FIG. 6 is explained by an example, wherein the signal diagram of FIG. 7 shows the signal level at different circuit nodes.

For example, two fault events occur, which are received at timing t1 at fault event assertion units 110_1 and 110_3, respectively. Thus, the outputs of the fault event assertion units 110_1 and 110_3 are set to a high level, for example (e.g., asserted fault event signals). This causes node A, which corresponds to the output of a first OR-gate OR1, to be set to a high level as well. Node A is fed into a second OR-gate OR2 and a latching element LT, which thus both set their respective outputs (nodes G and H) to a high level. A second AND-gate AND2 receives the signals at nodes H and G and consequently switches its output at node K to a high state. Node K controls the switching state of the switching device 134. In this example, a high level at node K turns switching device 134 on, thus fault output node 102 (and external fault signal F_ext) is pulled low, which indicates the fault operating state.

The outputs of the fault event assertion units 110_1, 1102, 110_3 are further connected to pulse extenders PE1, PE2, PE3, respectively. The pulse extenders PE1, PE2, PE3 are configured to extend the received pulse (when a fault event occurs) by different periods. This means that they will maintain their respective output at high level for different times after receiving a high pulse at their input. The outputs of the pulse extenders PE1, PE2, PE3 are provided to an XOR-gate XOR. The output of the XOR-gate XOR at node B is set to a high level when the number of high level inputs is odd. In case of three inputs this will be the case if only one or all three inputs are high. If all inputs are low or two inputs are high, node B will be low. Thus, in the present example, node B remains low as long as both the output of PE1 and the output of PE3 are high, and is switched to high as soon as the output of PE1 drops to low, and is switched to low again when the output of PE3 drops to low.

In this example, the outputs of the fault event assertion units 110_1, 110_3 are set to a low state at timing t2 after a predetermined time interval has elapsed after asserting the fault event signal at timing t1. This causes node A to go to low as well at this timing.

The node A is further connected to a voltage ramp generator Vramp, such as a sawtooth generator. The voltage ramp generator Vramp is triggered by the falling edge of the signal at node A, and thus starts providing a ramping voltage at node C at timing t2. Note that the output of the voltage ramp generator Vramp (node C) is set to high when the voltage ramp generator Vramp is inactive (e.g., before timing t2).

The circuit further includes two comparators Co1, Co2. The first comparator Co1 receives, at its non-inverting input Co1 (+) the signal of node C, and receives at its inverting input Co1 (−) the signal of node B. We note that the high level at node B (output of XOR-gate XOR) is set to a value between the lower and upper signal level of the voltage ramp provided by the voltage ramp generator Vramp at node C. Thus, the highest level provided by the voltage ramp generator Vramp is above the high level of XOR-gate XOR. As a consequence, the output of the first comparator Co1 (node D) will be in a high state as long as the voltage ramp generator Vramp is inactive (because node C is maintained in the high state), and will be switched between high and low states based on a comparison of the signals at nodes B and C when the voltage ramp generator Vramp is active. Thus, when both the voltage ramp generator Vramp is active and node B is set to a high state, pulses with a defined length are provided at node D, as is shown in FIG. 7. The second comparator Co2 receives, at its non-inverting input Co2(+), the signal of node C, and receives at its inverting input Co2(−) a reference voltage Vref. We note that the reference voltage Vref is set to a value between the lower and upper signal level of the voltage ramp provided by the voltage ramp generator Vramp at node C. The output of the second comparator Co2 (node E), will be in a high state as long as the voltage ramp generator Vramp is inactive (because node C is maintained in a high state in this case), and will be switched between high and low states based on a comparison of the signal level at node C with the reference voltage Vref when the voltage ramp generator Vramp is active, as is shown in FIG. 7. Since the reference voltage Vref is constant, pulses with a defined length will be provided at node E when the voltage ramp generator Vramp is active.

The reference voltage Vref is set to a lower value than the high level of XOR-gate XOR. This has the effect that the comparators Co1, Co2, which receive the same ramping voltage signal at their non-inverting inputs, switch their respective outputs (nodes D and E) from low to high at different times during the ramping of the voltage. Consequently, the pulses at nodes D and E have different length, where the pulse at node D has a longer low period compared to the pulse at node E.

A first AND-gate AND1 receives the signals at nodes D and E and provides at its output (node F) a high level when both inputs are high. As can be seen in FIG. 7, the signal at node F corresponds to a binary signal including data bits with a bit period that is defined by the ramping voltage. Additionally, the signal has a leading synchronization pulse corresponding to every data bit. The signal at node F may be referred to as a binary fault mode signal S20 that encodes information relating to the fault events as asserted by the fault detector 110. The signal at node F in the present example may be read as “100”, which may indicate that the fault events relating to fault event assertion units 110_1 and 110_3 have occurred.

The node F is further fed into the second OR-gate OR2, beside node A. As mentioned above, node A is switched to low at timing t2. Therefore, after timing t2, the output of second OR-gate OR2 (node G) is same as node F.

The second AND-gate AND2 receives the signals of node H, which is maintained high between timing t1 and t3, and of node G, which is switched as described above. Therefore, the output of second AND-gate AND2 (node K) copies that of node G (which is equal to node F) between timings t2 and t3. Thus, the switching device 134 is effectively switched in accordance with node F between timings t2 and t3, and therefore switched in accordance with binary fault mode signal S20 as described above. In this example, the signal level at fault output node 102 (external fault signal F_ext) is the inverted signal of node K, which however contain the same information.

In particular, the external fault signal F_ext has a leading low period between timings t1 and t2 to indicate the fault operating state. After timing t2, the signal is switched with a leading synchronization pulse for each data bit of binary fault mode signal S20. Thus, an external electronic circuit, such as a controller, can synchronize a sampling of the external fault signal F_ext based on a rising edge of the synchronization pulse (indicated with capital letter “T”), and the signal level at the sampling times (indicated with capital letter “S”) corresponds to the data bit value transmitted. In this example, the external fault signal F_ext transmits the word “011”. The external electronic circuit may be configured to decode this word as indicating that the two fault events associated with fault event assertion units 110_1 and 110_3 have occurred.

At timing t3, transmission of the fault mode signal S20 is completed, and the system resets itself, such that the fault output node 102 is switched back to the normal state (high level in this example).

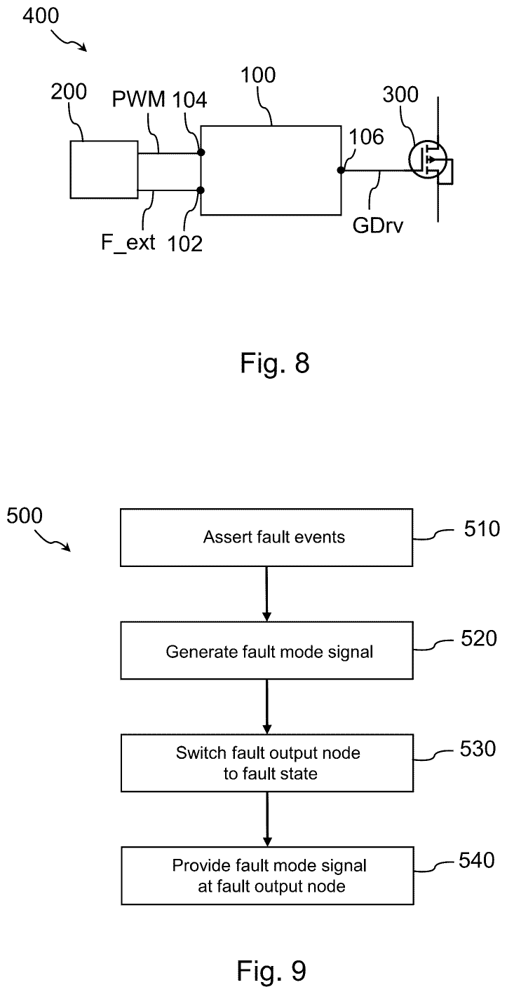

FIG. 8 shows a schematic block diagram of an electronic system 400 according to some embodiments of the present disclosure. The electronic system 400 includes a control unit 200 configured to control the electronic system 400, and the electronic circuit 100 according to one or more embodiments of the present disclosure. The control unit 200 is connected to the fault output node 102 of the electronic circuit 100, and may thus receive the fault signal F_ext provided at the fault output node 102 by the electronic circuit 100. Furthermore, the control unit 200 is configured to detect a fault operating state of the electronic system 400 based on the fault output node 102 being switched to the fault state. In addition, the control unit 200 is configured to receive the fault mode signal S20 at the fault output node 102 and to decode the received fault mode signal S20. Here, “decode” means that the control unit 200 may infer from the fault signal F_ext which fault events occurred in the electronic circuit 100. In other words, the control unit 200 is configured to determine, based on the fault signal F_ext, which fault events occurred in the electronic circuit 100. For example, the control unit 200 may use a look-up table for this. In some embodiments, the control unit 200 is configured to provide a reset signal RST_ext to the electronic circuit 100 to reset the electronic circuit 100 after a fault occurred (not shown in FIG. 8).

As an example, the electronic system 400 of FIG. 8 may implement an integrated power module, which may further comprise a power transistor 300. Additionally, the electronic circuit 100 may include a gate driver. The control unit 200 is configured to control a switching state of the power transistor 300 by providing a corresponding control signal PWM to the electronic circuit 100 at an input node 104. The gate driver provides, based on the control signal PWM, a gate drive signal GDrv at an output node 106 that is connected to the gate node of the power transistor 300. In some embodiments, the control unit 200 may be configured to stop providing the control signal PWM to the electronic circuit 100 in response to detecting the fault operating state of the electronic system 400.

In some embodiments, the control unit 200 may include a volatile or non-volatile memory configured to store some or all information transmitted from the electronic circuit 100 via the fault signal F_ext. Such information may be useful for system engineers when improving or designing a new power electronic system. In further embodiments, the control unit 200 may be configured to change an operation parameter of the electronic system in response to detecting the fault operating state of the electronic system and/or decoding the fault mode signal.

FIG. 9 depicts a schematic block diagram of an example of a method 500 for operating an electronic circuit 100 in accordance with the present disclosure. The method 500 includes a plurality of steps 510-540. In a first step 510, a number of fault event signals SF1a, SF2a of a plurality of fault event signals SF1, SF2 is asserted. Each one of the plurality of fault event signals SF1, SF2 indicates a different fault event associated with the electronic circuit 100. In a second step 520 a fault mode signal S20 is generated based on the asserted number of fault event signals SF1a, SF2a. In a third step 530 a fault output node 102 of the electronic circuit 100 is switched to a fault state. In a fourth step 540 the fault mode signal S20 is provided at the fault output node 102.

The order of the method steps may differ to what is shown in FIG. 9, and/or further steps may precede, intervene and/or follow the steps as shown in FIG. 9. For example, steps 520 and 530 may be interchanged in their order, and/or they may be performed simultaneously.

Although specific examples have been illustrated and described herein, it will be appreciated by those of ordinary skill in the art that a variety of alternate and/or equivalent implementations may be substituted for the specific examples shown and described without departing from the scope of the disclosed subject matter. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosed subject matter and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosed subject matter, as well as specific examples thereof, are intended to encompass equivalents thereof.

Some of the aspects explained above are briefly summarized in the following with reference to the following numbered examples.
Example 1. An electronic circuit including a fault output node switchable between a fault state indicating a fault operating state and a normal state indicating a normal operating state, the electronic circuit including:
a fault detector configured to assert a number of fault event signals of a plurality of fault event signals, wherein each one of the plurality of fault event signals indicates a different fault event associated with the electronic circuit,
a fault mode signal generator configured to generate a fault mode signal based on the asserted number of fault event signals, and
a fault output node control unit configured to receive the fault mode signal and, in response to receiving the fault mode signal:
switch the fault output node to the fault state, and output the fault mode signal at the fault output node by switching the fault output node in accordance with the fault mode signal.
Example 2. The electronic circuit of example 1, wherein:
the fault mode signal encodes one fault event signal asserted by the fault detector or a plurality of fault event signals asserted by the fault detector.
Example 3. The electronic circuit of any of the preceding examples, further including:
a reset unit configured to reset the fault detector and control the fault output node control unit to switch the fault output node to the normal state when a predefined reset time interval has elapsed after the fault output node control unit has switched the fault output node to the fault state.
Example 4. The electronic circuit of example 1 or 2, further including:
a reset unit configured to receive a reset signal and, in response to receiving the reset signal, reset the fault detector and control the fault output node control unit to switch the fault output node to the normal state.
Example 5. The electronic circuit of example 4, wherein fault output node control unit is configured to:
output the fault mode signal at the fault output node in response to the reset unit receiving the reset signal.
Example 6. The electronic circuit of any of the preceding examples, wherein:
the fault detector includes a plurality of fault event assertion units, wherein each fault event assertion unit includes an input, a storage element, and an output, and is configured to:
   receive one fault event signal at the input,
   store the received fault event signal in the storage element, and
   assert the stored fault event signal at the output.
Example 7. The electronic circuit of any of the preceding examples, wherein:
the fault output node control unit is configured to receive an electrical signal that is indicative of a measurement value relating to the operation of the electronic circuit, and to provide an analog signal corresponding to the received electrical signal at the fault output node during the normal operating state.
Example 8. The electronic circuit of any of the preceding example, wherein
the fault output node control unit is configured to output the fault mode signal by switching the fault output node to one of a plurality of distinct states corresponding to the fault mode signal.
Example 9. The electronic circuit of any of the preceding examples, wherein:
the fault mode signal is a binary signal including a plurality of data bits and the fault output node control unit is configured to output the fault mode signal by switching the fault output node between a first state and a second state in accordance with the binary fault mode signal.
Example 10. The electronic circuit of example 9, wherein the binary fault mode signal includes at least three data bits.
Example 11. The electronic circuit of example 9 or 10, wherein:
the fault output node control unit is configured to control a switching device connected between the fault output node and a reference potential to switch between a blocking state and a conductive state.
Example 12. The electronic circuit of any of examples 9 to 11, wherein:
the fault output node control unit is configured to output the data bits of the binary fault mode signal synchronous with a clock signal.
Example 13. The electronic circuit of any of examples 9 to 12, wherein:
the fault output node control unit is configured to output the data bits of the binary fault mode signal with a synchronization signal corresponding to every bit.
Example 14. The electronic circuit of any of the preceding examples, wherein:
the plurality of fault event signals includes at least two of the following:
   an overcurrent fault event signal
   an overvoltage fault event signal
   an undervoltage fault event signal
   a short-circuit fault event signal
   an overtemperature fault event signal
   a not ready fault event signal.
Example 15. The electronic circuit of any of the preceding examples, wherein at least one of the fault detector, the fault mode signal generator and the fault output node control unit is implemented as a digital circuit.
Example 16. The electronic circuit of any of the preceding examples, further comprising:
a gate driver configured to control a switching state of a connected power transistor based on a control signal, and
at least two fault event detectors, each one configured to detect a fault operating state of one of the gate driver or the connected power transistor and to output a corresponding fault event signal.
Example 17. The electronic circuit of any of the preceding examples, further comprising:
   a plurality of power transistors connected to at least one load node and configured to provide output power to the at least one load node, and
at least two fault event detectors configured to detect a fault operating state of the electronic circuit and to output a corresponding fault event signal.
Example 18: The electronic circuit of any of the preceding examples, wherein the fault output node control unit is configured to: switch the fault output node between the fault state and the normal state in accordance with the fault mode signal.
Example 19. An electronic system, including:
a control unit configured to control the electronic system, and
the electronic circuit of any of examples 1 to 18, wherein:
   the control unit is connected to the fault output node of the electronic circuit and configured to: detect a fault operating state of the electronic system based on the fault output node being switched to the fault state, receive the fault mode signal at the fault output node, and decode the received fault mode signal.
Example 20. A method for operating an electronic circuit, the method including the steps of:
Asserting a number of fault event signals of a plurality of fault event signals, wherein each one of the plurality of fault event signals indicates a different fault event associated with the electronic circuit,
Generating a fault mode signal based on the asserted number of fault event signals,
Switching a fault output node of the electronic circuit to a fault state, and
Providing the fault mode signal at the fault output node.

1. An electronic circuit comprising a fault output node switchable between a fault state indicating a fault operating state and a normal state indicating a normal operating state, the electronic circuit comprising:
a fault detector configured to assert a number of fault event signals of a plurality of fault event signals, wherein each of the plurality of fault event signals indicates a different fault event associated with the electronic circuit,
a fault mode signal generator configured to generate a fault mode signal based on the asserted number of fault event signals, and
a fault output node control unit configured to receive the fault mode signal and, in response to receiving the fault mode signal:
switch the fault output node to the fault state, and
output the fault mode signal at the fault output node by switching the fault output node in accordance with the fault mode signal.

2. The electronic circuit of claim 1, wherein:
the fault mode signal encodes one fault event signal asserted by the fault detector or a plurality of fault event signals asserted by the fault detector.

3. The electronic circuit of claim 1, further comprising:
a reset unit configured to reset the fault detector and control the fault output node control unit to switch the fault output node to the normal state when a predefined reset time interval has elapsed after the fault output node control unit has switched the fault output node to the fault state.

4. The electronic circuit of claim 1, further comprising:
a reset unit configured to receive a reset signal and, in response to receiving the reset signal, reset the fault detector and control the fault output node control unit to switch the fault output node to the normal state.

5. The electronic circuit of claim 4, wherein the fault output node control unit is configured to:
output the fault mode signal at the fault output node in response to the reset unit receiving the reset signal.

6. The electronic circuit of claim 1, wherein:
the fault detector comprises a plurality of fault event assertion units, wherein each fault event assertion unit comprises an input, a storage element, and an output, and is configured to:
receive one fault event signal at the input,
store the received fault event signal in the storage element, and
assert the stored fault event signal at the output.

7. The electronic circuit of claim 1, wherein:
the fault output node control unit is configured to receive an electrical signal that is indicative of a measurement value relating to the operation of the electronic circuit, and to provide an analog signal corresponding to the received electrical signal at the fault output node during the normal operating state.

8. The electronic circuit of claim 1, wherein
the fault output node control unit is configured to output the fault mode signal by switching the fault output node to one of a plurality of distinct states corresponding to the fault mode signal.

9. The electronic circuit of claim 1, wherein:
the fault mode signal is a binary fault mode signal comprising a plurality of data bits and the fault output node control unit is configured to output the fault mode signal by switching the fault output node between a first state and a second state in accordance with the binary fault mode signal.

10. The electronic circuit of claim 9, wherein the binary fault mode signal comprises at least three data bits.

11. The electronic circuit of claim 9, wherein:
the fault output node control unit is configured to control a switching device connected between the fault output node and a reference potential to switch between a blocking state and a conductive state.

12. The electronic circuit of claim 9, wherein:
the fault output node control unit is configured to output the plurality of data bits of the binary fault mode signal synchronous with a clock signal.

13. The electronic circuit of claim 9, wherein:
the fault output node control unit is configured to output the plurality of data bits of the binary fault mode signal with a synchronization signal corresponding to every bit.

14. The electronic circuit of claim 1, wherein:
the plurality of fault event signals comprises at least two of:
an overcurrent fault event signal,
an overvoltage fault event signal,
an undervoltage fault event signal,
a short-circuit fault event signal,
an overtemperature fault event signal, or
a not ready fault event signal.

15. The electronic circuit of claim 1, wherein at least one of the fault detector, the fault mode signal generator or the fault output node control unit is implemented as a digital circuit.

16. The electronic circuit of claim 1, further comprising:
a gate driver configured to control a switching state of a connected power transistor based on a control signal, and
at least two fault event detectors, each configured to:
detect a fault operating state of one of the gate driver or the connected power transistor, and
output a corresponding fault event signal.

17. The electronic circuit of claim 1, further comprising:
a plurality of power transistors connected to at least one load node and configured to provide output power to the at least one load node, and
at least two fault event detectors configured to detect a fault operating state of the electronic circuit and to output a corresponding fault event signal.

18. The electronic circuit of claim 1, wherein the fault output node control unit is configured to:
switch the fault output node between the fault state and the normal state in accordance with the fault mode signal.

19. An electronic system, comprising:
a control unit configured to control the electronic system, and
an electronic circuit comprising a fault detector, a fault mode signal generator and a fault output node control unit,
wherein the control unit is connected to a fault output node of the electronic circuit and configured to:
detect a fault operating state of the electronic system based on the fault output node being switched to a fault state,
receive a fault mode signal at the fault output node, and
decode the received fault mode signal.

20. A method for operating an electronic circuit, the method comprising:
asserting a number of fault event signals of a plurality of fault event signals, wherein each of the plurality of fault event signals indicates a different fault event associated with the electronic circuit,
generating a fault mode signal based on the asserted number of fault event signals,
switching a fault output node of the electronic circuit to a fault state, and
providing the fault mode signal at the fault output node.
